(19) United States
(12) Patent Application Publication
(10) Pub. No.: US 2006/0112880 A1
(43) Pub. Date: Jun. 1, 2006

(54) Treating apparatus

(76) Inventors: Katsuhiko Iwabuchi, Kanagawa (JP); Toshiki Kobayashi, Kanagawa (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/290,467

(22) Filed: Dec. 1, 2005

(30) Foreign Application Priority Data
Dec. 1, 2004 (JP) 2004-348916
Oct. 17, 2005 (JP) 2005-301722

(51) Int. Cl. C23C 16/00

(52) U.S. Cl. 118/724

(57) ABSTRACT

A treating apparatus for spreading treatment gas uniformly all over a to-be-treated substrate mounted on a substrate mount while controlling the heat transfer rate between the substrate and the substrate mount to thereby uniformize the temperature of the to-be-treated substrate over the whole surface thereof. A porous substrate having a large number of communicating pores serves as the mount for treating the to-be-treated substrate mounted on the substrate mount disposed in a vacuum vessel while controlling the temperature of the to-be-treated substrate into a predetermined temperature. In the porous substrate, a large number of communicating pores are formed in a substrate to communicate with one another in all directions. The treatment gas diffuses uniformly from below through the communicating pores and spouts upward. An electrostatically chucking electrode is buried in a gas-permeable insulating film. The porous substrate is peripherally coated with a heat resistant insulating film of ceramics etc.

### FIELD OF THE INVENTION

The present invention relates to a treating apparatus for treating a to-be-treated substrate such as a glass substrate mounted on a mount disposed in a vacuum vessel while controlling the temperature of the to-be-treated substrate into a predetermined temperature, and particularly relates to a configuration of the substrate mount of the treating apparatus.

### DESCRIPTION OF THE BACKGROUND ART

In a treating apparatus for performing plasma treatment or the like upon the surface of a to-be-treated substrate (hereinafter also referred to as “substrate” simply), a substrate mount having a function as an electrostatic chuck for mounting and fixing the substrate is used. In the substrate mount, a large number of narrow holes are opened in the substrate mounting area thereof, or processing such as grooving or dimpling is performed, so that various kinds of gases for surface treatment can be supplied to the whole area of the mounted substrate. JP-A-2002-222799 discloses a plasma treatment apparatus in which a corrosion resistant film is formed around a substrate mount made of a carbon substrate so as to prevent corrosion with oxygen gas. JP-A-6-216224 discloses a substrate mount with an electrostatic chuck in which a ceramic plate is brazed with a metal substrate. JP-A-5-152425 discloses a substrate mount in which an electrostatic adsorption electrode is buried in a heater block where a heater (heating elements) is planted. JP-A-6-279974 discloses a substrate mount in which a conductor portion exposed from a ceramic substrate is coated with an insulating spray deposit.

In the aforementioned background art, however, it is difficult to diffuse gas uniformly over the whole area of the to-be-treated substrate mounted on the substrate mount. In addition, there occurs a variation of heat transfer in the contact surface between the substrate mount and the to-be-treated substrate. It is therefore difficult to perform substrate treatment with high quality.

### SUMMARY OF THE INVENTION

An object of the present invention is to provide a treating apparatus in which gas can be diffused uniformly over the whole area of a to-be-mounted substrate mounted on a substrate mount, and the whole area of the surface of the substrate can be treated uniformly.

Typical configurations of the present invention to attain the foregoing object will be described below. That is, according to the invention, a treating apparatus for performing various surface treatments upon a to-be-treated substrate mounted on a mount disposed in a vacuum vessel while controlling the temperature of the to-be-treated substrate into a predetermined temperature is designed as:

(1) the mount is made of a porous substrate having communicating pores; and

gas supplied to the communicating pores on the opposite side of the porous substrate to the to-be-treated substrate is spouted to a surface of the to-be-treated substrate facing the mount.

(2) A gas supply means is provided for supplying gas to the communicating pores from the opposite side of the porous substrate to the to-be-treated substrate;

a surface portion of the porous substrate facing the to-be-treated substrate is coated with a gas-permeable insulating film while the other surface portion of the porous substrate is coated with a non-gas-permeable insulating film;

an electrostatically chucking electrode is buried inside the gas-permeable insulating film in the surface portion of the porous substrate on the surface side where the to-be-treated substrate is mounted;

an electrostatically chucking DC power supply is provided for applying electrostatic potential to the electrostatically chucking electrode; and

the gas supplied to the communicating pores of the porous substrate from the opposite side to the to-be-treated substrate is spouted uniformly through the communicating pores of the porous substrate to the surface side where the to-be-treated substrate is mounted.

(3) An electrostatically chucking electrode is buried inside the surface portion of the porous substrate on the surface side where the to-be-treated substrate is mounted, in the state where the peripheral surface of the electrostatically chucking electrode is coated with an electrically insulating coating;

a gas supply means is provided for supplying gas to the communicating pores of the porous substrate, and an electrostatically chucking DC power supply is provided for applying electrostatic potential to the electrostatically chucking electrode;

a surface portion of the porous substrate except a surface portion facing the to-be-treated substrate is peripherally coated with a non-gas-permeable insulating film; and

the gas supplied to the communicating pores of the porous substrate from the opposite side to the to-be-treated substrate is spouted uniformly through the communicating pores of the porous substrate to the surface side where the to-be-treated substrate is mounted.

(4) The gas supply means for supplying gas to the porous substrate includes:

a gas inlet for introducing the gas from the opposite side of the mount to the to-be-treated substrate;

a cylindrical gas filled portion extending from the gas inlet to a central portion of the porous substrate;

a gap portion formed into a sheet-like shape so as to extend broadly inside the porous substrate from one end of the gas filled portion; and

a large number of worked grooves provided at predetermined intervals or a large number of dimples provided independently of one another, in an inner wall surface of the porous substrate on the to-be-treated substrate side of the gap portion.

(5) Heating elements are planted in the porous substrate so as to be joined integrally therewith, and an AC power supply is provided for supplying power to the heating elements from the opposite side of the mount to the to-be-treated substrate.

(6) A surface portion of the porous substrate facing the to-be-treated substrate is coated with a gas-permeable insulating film while the other surface portion of the porous substrate is coated with a non-gas-permeable insulating film;

an AC power supply is provided for supplying power to the heating elements from the opposite side of the mount to the to-be-treated substrate, while a gas supply means is provided for supplying gas to the communicating pores of the porous substrate; and

the gas supply means includes a gas inlet for introducing the gas from the opposite side of the mount to the to-be-treated substrate, a cylindrical gas filled portion extending from the gas inlet to a central portion of the porous substrate, a gap portion formed into a sheet-like shape so as to extend broadly inside the porous substrate from one end of the gas filled portion, and a large number of worked grooves provided at predetermined intervals or a large number of dimples provided independently of one another, in an inner wall surface of the porous substrate on the to-be-treated substrate side of the gap portion.

As for the material to the porous substrate, carbon or corrosion-resistant metals may be provided. Several metals, e.g., nickel (Ni), copper (Cu), or those alloys may be useful.

According to the present invention, it is possible to obtain the following excellent effects. That is:

In a treating apparatus for treating a to-be-treated substrate mounted on amount in a vacuum vessel while controlling the temperature of the to-be-treated substrate into a predetermined temperature, gas is supplied uniformly to the back surface of the substrate through communicating pores of a porous substrate of the mount. It is therefore possible to control uniformly the temperature of the to-be-treated substrate over the whole area of the substrate surface.

The porous substrate of the mount is stable at high temperature and excellent in heat conductivity. Accordingly, the porous substrate is heated easily by various treatment gases (e.g. heat conductive gas) introduced through the communicating pores of the porous substrate. In addition, due to the heating elements such as sheath heaters planted inside the mount, the porous substrate can be heated easily in a short time. As a result, the temperature of the mount can be controlled accurately and rapidly.

Further, the peripheral surface of the porous substrate of the mount except the surface facing the to-be-treated substrate is coated with a non-gas-permeable insulating film. Accordingly, heat conductive gas is intensively hit against only the back surface (the side facing the mount) of the to-be-treated substrate. Thus, the efficiency in heating the to-be-treated substrate is excellent, and consumption of the porous substrate caused by oxidation is prevented. When inert gas is used as the heat conductive gas, consumption of the mount of the porous substrate caused by oxidation can be prevented perfectly. Thus, excellent durability can be obtained.

### BRIEF DESCRIPTION OF THE DRAWINGS

FIG. 1 is a main portion longitudinally sectional view for explaining a first embodiment of a treating apparatus including a substrate mount made of a porous substrate having communicating pores according to the present invention;

FIG. 2 is a partially enlarged explanatory view showing the state where gas is permeating the porous substrate of the substrate mount in FIG. 1;

FIG. 3 is an enlarged explanatory view of the porous substrate having the communicating pores;

FIG. 4 is a main portion enlarged sectional view similar to FIG. 2, for explaining a second embodiment of a treating apparatus including a substrate mount made of a porous substrate having communicating pores according to the present invention;

FIG. 5 is a longitudinally sectional view for explaining an example of the whole configuration of the second embodiment of the treating apparatus including the substrate mount made of the porous substrate having the communicating pores according to the present invention; and

FIG. 6 is a longitudinally sectional view for explaining a third embodiment of a treating apparatus including a substrate mount made of a porous substrate having communicating pores according to the present invention.

### DETAILED DESCRIPTION OF THE INVENTION

Preferred embodiments of the present invention will be described below in detail with reference to the drawings.

These embodiments are described in the case of the material of porous substrate to be carbon. With corrosion-resistant metals may be provided in the same way as in the case of carbon.

### FIRST EMBODIMENT

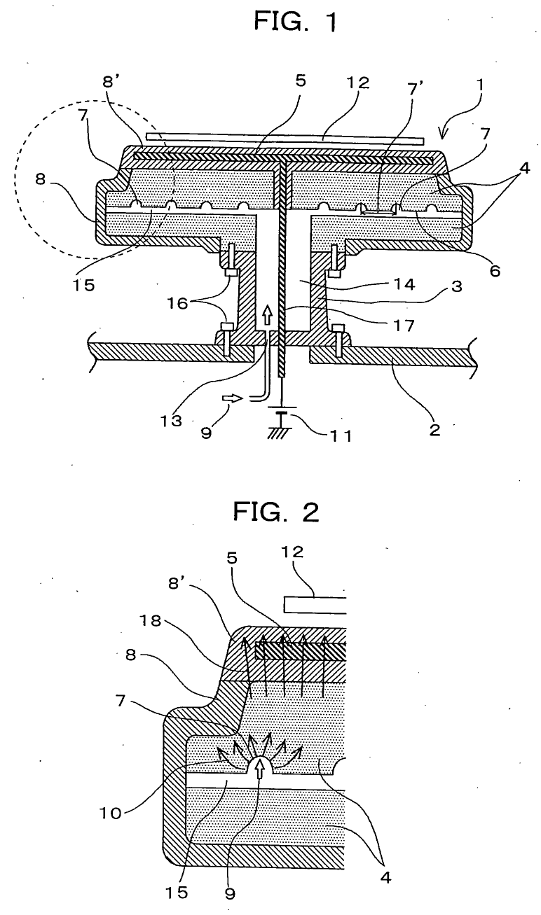

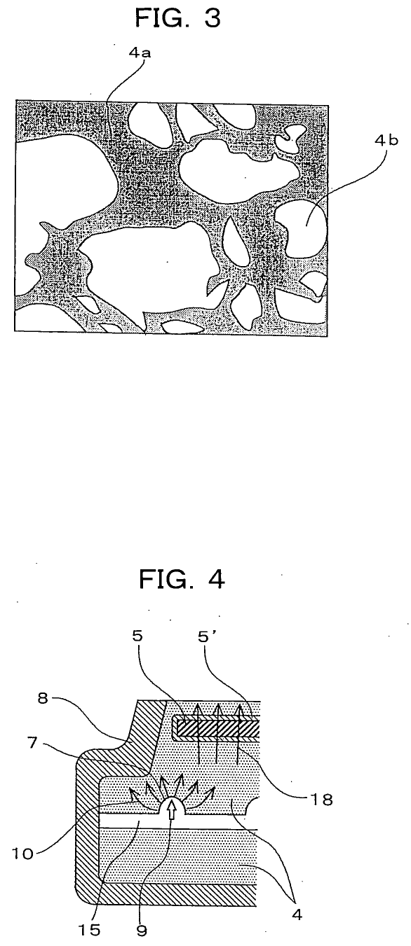

FIG. 1 is a main portion longitudinally sectional view for explaining a first embodiment of a treating apparatus constituted by a substrate mount made of a porous carbon substrate having communicating pores according to the invention. FIG. 2 is a partially enlarged explanatory view showing the state where gas is permeating (passing) the porous carbon substrate of the substrate mount in FIG. 1. FIG. 3 is an enlarged explanatory view of the porous carbon substrate having communicating pores according to the first embodiment. In FIGS. 1-3, the reference numeral 1 represents a substrate mount; 2, a vacuum vessel; 3, a mount base (hereinafter referred to as “heater base”); 4, a porous carbon substrate; 4a, a carbon substrate; 4b, a communicating pore; 5, an electrostatically chucking electrode; 6, a carbon substrate bonding portion; 7, a grooved portion; 7′, a predetermined interval; 8, a non-gas-permeable insulating film; 8′, a gas-permeable insulating film; 9, gas; 10, flow of the gas; 11, a DC power supply; 12, a to-be-treated substrate; 13, a gas inlet; 14, a gas filled portion; 15, a gap portion; 16, a setscrew; 17, a lead wire; and 18, flow of heat transfer.

The treating apparatus according to the first embodiment treats the to-be-treated substrate (substrate) 12 mounted on the substrate mount (hereinafter also referred to as “mount” simply) disposed in the vacuum vessel 2 (only a part of the wall of the vacuum vessel is shown in FIG. 1) while controlling the temperature of the to-be-treated substrate 12 into a predetermined temperature. The mount 1 is made of the porous carbon substrate 4 which has good heat conductivity and includes a large number of communicating pores. As shown in the enlarged view of FIG. 3, in the porous carbon substrate 4, a large number of communicating pores 4b communicating with one another in all directions are formed in the carbon substrate 4a. The gas 9 passing (or permeating) the communicating pores 4b from one surface side of the porous carbon substrate 4 is spouted from the other surface side of the porous carbon substrate 4 so as to be diffused uniformly. The electrostatically chucking electrode 5 is buried in the gas-permeable insulating film 8′.

Further, a gas supply means is provided for supplying the gas 9 (e.g. He gas) to the porous carbon substrate 4. The electrostatically chucking DC power supply 11 is provided for applying electrostatic potential to the electrostatically chucking electrode 5 buried in an upper portion of the mount 1. The porous carbon substrate 4 is peripherally coated with the heat-resistant insulating film 8 of ceramics or the like.

As the gas supply means for supplying the gas 9 to the porous carbon substrate 4, the gas inlet 13 and the cylindrical gas filled portion 14 are disposed. The gas inlet 13 penetrates the bottom of the heater base 3 disposed inside the bottom of the vacuum vessel 2 in a lower portion of the mount 1. The gas filled portion 14 extends from the gas inlet 13 to a central portion of the porous carbon substrate 4. The gap portion 15 is formed into a sheet-like shape extending broadly inside the porous carbon substrate 4 from the center top of the gas filled portion 14. Further, the porous carbon substrate bonding portions 6 on the top of the gap portion 15 are provided to sink at the predetermined intervals 7′. Thus, the porous carbon substrate 4 to be bonded is grooved to form the grooved portions 7. A large number of dimpled concave holes (not shown) may be provided independently of one another instead of the grooved portions.

The lead wire 17 provided to extend from the central portion of the electrostatically chucking electrode 5 toward the illustrated bottom (opposite to the side where the substrate should be mounted) is connected to the external DC power supply 11 through the gas inlet 13.

As shown in the enlarged view of FIG. 2, of the porous carbon substrate, the portion serving to be permeable to gas is designed so that the gas 9 passing through the gap 15 and reaching the left-end grooved portion 7 is transmitted upward from the contact portion with the porous carbon substrate 4 through the communicating pores of the carbon substrate 4 as shown by the gas flows 10. Accordingly, the gas 9 is uniformly supplied to the porous carbon substrate 4. It is therefore possible to transfer heat uniformly without any variation to the to-be-treated substrate 12 as shown by the heat transfer flows 18.

### SECOND EMBODIMENT

FIG. 4 is a main portion enlarged sectional view similar to FIG. 2. FIG. 4 explains a second embodiment of a treating apparatus including a substrate mount made of a porous carbon substrate having communicating pores according to the present invention. Parts functionally the same as those in FIG. 2 are referenced correspondingly. The reference numeral 5′ represents a gas-permeable insulating coating. The treating apparatus according to the second embodiment treats a to-be-treated substrate 12 mounted on a mount 1 disposed in a vacuum vessel 2 while controlling the temperature of the to-be-treated substrate 12 into a predetermined temperature.

The mount 1 shown in FIG. 1 is formed out of a porous carbon substrate 4 having communicating pores. An electrostatically chucking electrode 5 is buried into the top (substrate mounting side) of the porous carbon substrate 4 in the state where the peripheral surface of the electrostatically chucking electrode 5 is coated with the electrically insulating coating 5′. A gas supply means is provided for supplying gas to the communicating pores of the porous carbon substrate 4. An electrostatically chucking DC power supply 11 is provided for applying electrostatic potential to the electrostatically chucking electrode 5.

Further, the peripheral surface of the porous carbon substrate 4 except the surface facing the to-be-treated substrate 12 is coated with a non-permeable insulating film 8. Thus, gas 9 supplied from below to the communicating pores of the porous carbon substrate 4 is transmitted through the communicating pores of the porous carbon substrate 4 and spouted uniformly to the back surface of the substrate 12.

As shown in FIG. 4, the gas 9 passing through a gap 15 and reaching a left-end grooved portion 7 is transmitted upward from the contact portion with the porous carbon substrate 4 through the communicating pores of the carbon substrate 4 as shown by arrows 10. Accordingly, the gas 9 is uniformly supplied to the porous carbon substrate 4. It is therefore possible to transfer heat uniformly without any variation to the substrate 12 as shown by heat transfer flows 18.

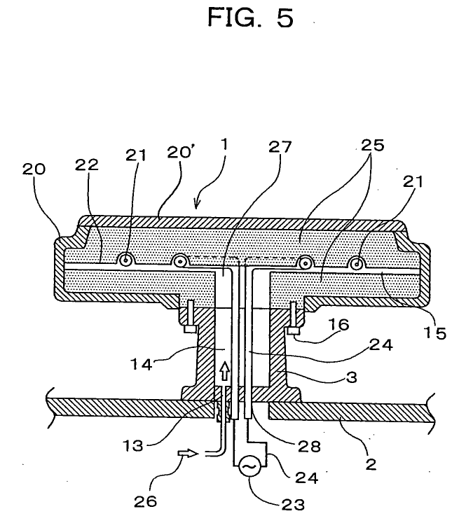

FIG. 5 is a longitudinally sectional view for explaining an example of the whole configuration of the treating apparatus according to the second embodiment. FIG. 5 shows the state where a carbon heater substrate is formed by planting heating elements into the porous carbon substrate, and inert gas is introduced into a gap between the porous carbon substrate and each planted heating element, while the peripheral surface of the carbon heater substrate is coated with an insulating spray deposit. In FIG. 5, the reference numeral 20 represents a non-gas-permeable insulating film; 21, a heating element (sheath heater); 22, a gap; 23, a heater power supply; 24, a heater cord; 25, a porous carbon substrate; 26, inert gas; and 27, an inert gas atmosphere.

This treating apparatus treats a to-be-treated substrate 12 mounted on a mount 1 disposed in a vacuum vessel 2 illustrated by its wall surface, while controlling the temperature of the to-be-treated substrate 12 into a predetermined temperature. The treating apparatus is configured as follows. That is, after the heating elements 21 (sheath heater) are planted between two upper and lower split pieces of the porous carbon substrate 25, the two pieces of the porous carbon substrate are bonded integrally with each other with the gap 22 being set therebetween. The porous carbon substrate 25 integrated thus serves as a carbon heater substrate forming the substrate mount 1. Of the carbon heater substrate forming the substrate mount 1, the surface facing the to-be-treated substrate 12 is coated with a gas-permeable insulating film 20′, and the other peripheral surface thereof is coated with the non-gas-permeable insulating film 20. This insulating film may be, for example, a heat resistant ceramic spray deposit.

Further, the heater power supply 23 is provided for supplying power to the heating elements 21 from the bottom of the vacuum vessel 2. A pair of heater cords 24 are disposed to extend from the heater power supply 23 through cord insertion holes 28 to the central portion of the porous carbon substrate 25 forming the carbon heater substrate and further supply power to the heating elements 21 disposed at predetermined intervals around the center with respect to the thickness of the carbon heater substrate. The heating elements 21 are fixedly retained in the bonding portion 22 between the two pieces of the porous carbon substrate 25 forming the carbon heater substrate.

A cylindrical gas filled portion 14 is disposed as a gas supply means for supplying the inert gas 26 toward the carbon heater substrate formed out of the porous carbon substrate 25. The gas filled portion 14 extends to the central portion of the carbon heater substrate from an inert gas inlet 13 penetrating the bottom of a heater base 3 disposed inside the bottom of the vacuum vessel 2 in a lower portion of the mount 1. A gap 15 is formed into a sheet-like shape extending broadly inside the carbon heater substrate from the center top of the filled portion 14. Therefore, an inert gas atmosphere 27 filled with the inert gas is formed. Further, in the upper surface of the gap 15, the heating elements 21 are planted at predetermined intervals in the porous carbon substrate 25 forming the carbon heater substrate.

According to the second embodiment described above, there is no fear that oxidizing gas touches the carbon heater substrate formed out of the porous carbon substrate 25. In addition, inert gas is introduced into the inside of the porous carbon substrate 25. Thus, consumption of the porous carbon substrate caused by oxidation can be suppressed. Further, the inert gas is charged into the gas between the porous carbon substrate and each heating element. Thus, the heat transfer efficiency is improved.

### THIRD EMBODIMENT

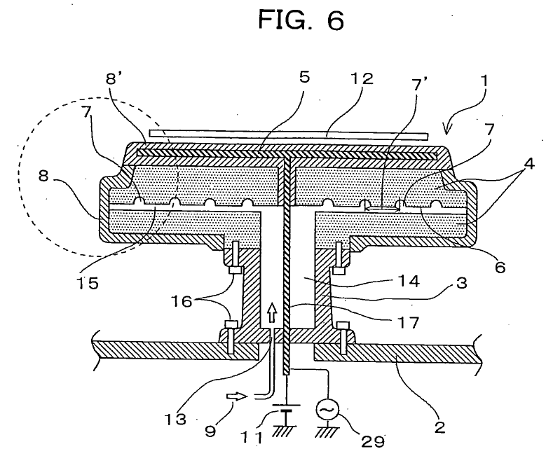

FIG. 6 is a longitudinally sectional view for explaining a third embodiment of a treating apparatus including a substrate mount made of a porous carbon substrate having communicating pores according to the present invention. In the third embodiment, a high frequency power supply 29 together with the DC power supply 11 is provided as a power supply for applying power to the electrostatically chucking electrode 5 in the first embodiment described with reference to FIG. 1. A high frequency current supplied from the high frequency power supply 29 is superimposed on a current from the DC power supply 11 and applied to the electrostatically chucking electrode 5. When the high frequency current is superimposed, the electrostatic attractive force is improved. The other configuration is similar to that in the first embodiment described with reference to FIG. 1.

Also according to the third embodiment described above, gas is supplied uniformly to the back surface of the to-be-treated substrate through the communicating pores of the porous carbon substrate of the mount in the same manner as in the first embodiment. Accordingly, the temperature of the to-be-treated substrate can be controlled uniformly all over the substrate.

What is claimed is:

1. A treating apparatus for treating a to-be-treated substrate while controlling the temperature of the to-be-treated substrate into a predetermined temperature, comprising:
a vacuum vessel; and
a mount disposed in the vacuum vessel, mounted with the to-be-treated substrate, and made of a porous substrate having communicating pores;
wherein gas supplied to the communicating pores on the opposite side of the porous substrate to the to-be-treated substrate is spouted to a surface of the to-be-treated substrate facing the mount.

2. A treating apparatus for treating a to-be-treated substrate while controlling the temperature of the to-be-treated substrate into a predetermined temperature, comprising:
a vacuum vessel;
a mount disposed in the vacuum vessel, mounted with the to-be-treated substrate, and made of a porous substrate having communicating pores, a surface portion of the porous substrate facing the to-be-treated substrate being coated with a gas-permeable insulating film while the other surface portion of the porous substrate is coated with a non-gas-permeable insulating film;
a gas supply means for supplying gas to the communicating pores from the opposite side of the porous substrate to the to-be-treated substrate;
an electrostatically chucking electrode buried inside the gas-permeable insulating film in the surface portion of the porous substrate on the surface side where the to-be-treated substrate is mounted; and
an electrostatically chucking DC power supply for applying electrostatic potential to the electrostatically chucking electrode;
wherein the gas supplied to the communicating pores of the porous substrate from the opposite side to the to-be-treated substrate is spouted uniformly through the communicating pores of the porous substrate to the surface side where the to-be-treated substrate is mounted.

3. A treating apparatus for treating a to-be-treated substrate while controlling the temperature of the to-be-treated substrate into a predetermined temperature, comprising:
a vacuum vessel;
a mount disposed in the vacuum vessel, mounted with the to-be-treated substrate, and made of a porous substrate having communicating pores, a surface portion of the porous substrate except a surface portion facing the to-be-treated substrate is peripherally coated with a non-gas-permeable insulating film;
an electrostatically chucking electrode buried inside the surface portion of the porous substrate on the surface side where the to-be-treated substrate is mounted, in the state where the peripheral surface of the electrostatically chucking electrode is coated with an electrically insulating coating;
a gas supply means for supplying gas to the communicating pores of the porous substrate; and
an electrostatically chucking DC power supply for applying voltage to the electrostatically chucking electrode;
wherein the gas supplied to the communicating pores of the porous substrate from the opposite side to the to-be-treated substrate is spouted uniformly through the communicating pores of the porous substrate to the surface side where the to-be-treated substrate is mounted.

4. A treating apparatus according to any one of claims 1 through 3, wherein the gas supply means for supplying gas to the porous substrate includes:
a gas inlet for introducing the gas from the opposite side of the mount to the to-be-treated substrate;
a cylindrical gas filled portion extending from the gas inlet to a central portion of the porous substrate;
a gap portion formed into a sheet-like shape so as to extend broadly inside the porous substrate from one end of the gas filled portion; and
a large number of worked grooves provided at predetermined intervals or a large number of dimples provided independently of one another, in an inner wall surface of the porous substrate on the to-be-treated substrate side of the gap portion.

5. A treating apparatus according to any one of claims 1 through 3, further comprising:
heating elements planted in the porous substrate so as to be joined integrally therewith; and
an AC power supply for supplying power to the heating elements from the opposite side of the mount to the to-be-treated substrate.

6. A treating apparatus according to claim 4, further comprising:
heating elements planted in the porous substrate so as to be joined integrally therewith; and
an AC power supply for supplying power to the heating elements from the opposite side of the mount to the to-be-treated substrate.

7. A treating apparatus for treating a to-be-treated substrate while controlling the temperature of the to-be-treated substrate into a predetermined temperature, comprising:
a vacuum vessel;
a mount disposed in the vacuum vessel, mounted with the to-be-treated substrate, and made of a porous substrate having communicating pores, a surface portion of the porous substrate facing the to-be-treated substrate being coated with a gas-permeable insulating film while the other surface portion of the porous carbon substrate is coated with a non-gas-permeable insulating film;
heating elements planted in the porous substrate so as to be joined integrally therewith;
an AC power supply for supplying power to the heating elements from the opposite side of the mount to the to-be-treated substrate; and
a gas supply means for supplying gas to the communicating pores of the porous substrate, the gas supply means including:
a gas inlet for introducing the gas from the opposite side of the mount to the to-be-treated substrate;
a cylindrical gas filled portion extending from the gas inlet to a central portion of the porous substrate;
a gap portion formed into a sheet-like shape so as to extend broadly inside the porous substrate from one end of the gas filled portion; and
a large number of worked grooves provided at predetermined intervals or a large number of dimples provided independently of one another, in an inner wall surface of the porous substrate on the to-be-treated substrate side of the gap portion.
